(19) United States
(12) Patent Application Publication
(10) Pub. No.: US 2010/0301468 A1
(43) Pub. Date: Dec. 2, 2010

(54) SEMICONDUCTOR DEVICE AND METHOD OF MANUFACTURING THE SAME

(75) Inventors: Mitsuhisa WATANABE, Tokyo (JP); Keiyo Kusanagi, Tokyo (JP); Koichi Hatakeyama, Tokyo (JP); Hiroyuki Fujishima, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/787,770

(22) Filed: May 26, 2010

(30) Foreign Application Priority Data
May 27, 2009 (JP) 2009-127872

(51) Int. Cl. H01L 23/48; H01L 21/60; H01L 21/56

(52) U.S. Cl. 257/692; 438/124; 257/E23.01; 257/E21.502; 257/E21.506

(57) ABSTRACT

A semiconductor device may include, but is not limited to a wiring board, a first insulator, a semiconductor chip, and a second insulator. The first insulator penetrates the wiring board. A top end of the first insulator is higher in level than an upper surface of the wiring board. The semiconductor chip is disposed on the top end of the first insulator. The semiconductor chip is separated from the upper surface of the wiring board. The second insulator covers the semiconductor chip and the upper surface of the wiring board.

### BACKGROUND OF THE INVENTION

1. Field of the Invention

The present invention relates to a semiconductor device and a method of manufacturing the same.

Priority is claimed on Japanese Patent Application No. 2009-127872, filed May 27, 2009, the content of which is incorporated herein by reference.

2. Description of the Related Art

A BGA (Ball Grid Array) semiconductor device of the related arts includes: a wiring board having main and rear surfaces, multiple connection pads being provided on the main surface, and multiple lands being provided on the rear surface so as to electrically connect to the connection pads; a semiconductor chip on the main surface of the wiring board; a plurality of wires electrically connecting electrode pads on the semiconductor chip and connection pads on the wiring board; a seal resin that is made of an insulating resin and covers at least the semiconductor chip and the plurality of wires; and a plurality of external terminals (solder balls) on the respective lands. Such a semiconductor device is disclosed in, for example, Japanese Laid-Open Publication Nos. 2001-44229 and 2001-44324.

A semiconductor device including a semiconductor chip that is not attached and fixed onto a wiring board is disclosed in, for example, Japanese Laid-Open Publication Nos. S59-89423 and S62-92331. Specifically, a semiconductor chip is placed in a device hole provided in a circuit board (wiring board). The semiconductor chip is suspended by wires. The semiconductor chip, the wires, and the wiring board are partially sealed by liquid resin.

Regarding the semiconductor device disclosed in Japanese Laid-Open Publication Nos. 2001-44229 and 2001-44324, the semiconductor chip is attached and fixed onto the wiring board. For this reason, stress is generated due to the difference in thermal expansion coefficients between the semiconductor chip and the wiring board, and thereby the reliability of the semiconductor device might degrade.

Additionally, stress acts on a boundary between an area in which the semiconductor chip is provided and an area in which the semiconductor chip is not provided, especially on the four corners of the semiconductor chip. Consequently, external terminals (solder balls) under the stress-focused portions crack, and thereby the reliability of a secondary mounting of the semiconductor device might degrade.

Further, the difference in thermal expansion coefficients between the semiconductor chip and the wiring board causes warpage of the semiconductor device. Consequently, the mounting precision of the semiconductor device might degrade, and defective connection of solder balls to the mounting board might occur.

Regarding the semiconductor device disclosed in Japanese Laid-Open Publication Nos. S59-89423 and S62-92331, a surface of the semiconductor chip on the side of the wiring board is exposed, or a thin board is provided. For this reason, when DRAM (Dynamic Random Access Memory) is used as a semiconductor chip, stresses caused by the difference in thermal expansion among the wiring board, the seal resin, and the like differ, and thereby the refresh characteristics might degrade.

Additionally, since the surface of the semiconductor chip on the side of the wiring board is not covered by a seal resin, humidity resistance and mechanical strength of the semiconductor device might degrade.

Further, a through-hole, which is larger in size than the semiconductor chip, is formed in the wiring board, and the semiconductor chip is placed in the through-hole. For this reason, the size of the wiring board increases, thereby making it difficult to miniaturize the semiconductor device. Consequently, the demand for miniaturization of semiconductor devices along with the miniaturization of recent mobile devices cannot be satisfied, thereby increasing costs of semiconductor devices.

Moreover, if the number of terminals included in the semiconductor device increases, the size of the wiring board increases due to wire routing, and therefore the size of the semiconductor device might increase.

### SUMMARY

In one embodiment, a semiconductor device may include, but is not limited to a wiring board, a first insulator, a semiconductor chip, and a second insulator. The first insulator penetrates the wiring board. A top end of the first insulator is higher in level than an upper surface of the wiring board. The semiconductor chip is disposed on the top end of the first insulator. The semiconductor chip is separated from the upper surface of the wiring board. The second insulator covers the semiconductor chip and the upper surface of the wiring board.

In another embodiment, a method of manufacturing a semiconductor device may include, but is not limited to the following processes. A motherboard having a plurality of through-holes is prepared. A support board is attached onto the motherboard. The support board has a plurality of protruding portions. The plurality of protruding portions are inserted into the plurality of through-holes, so that top ends of the plurality of protruding portions are higher in level than an upper surface of the motherboard. A plurality of semiconductor chips are fixed to the top ends of the plurality of protruding portions so that the plurality of semiconductor chips is separated from the upper surface of the motherboard. A first insulator is formed so as to cover the plurality of semiconductor chips. The support board is removed. A second insulator is formed so as to fill a plurality of spaces into which the plurality of protruding portions have been inserted. The second insulator is connected to the first insulator.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plan view illustrating a semiconductor device according to a first embodiment of the present invention;

FIG. 2 is a cross-sectional view taken along line A-A′ shown in FIG. 1;

FIG. 3A is a plan view illustrating a wiring board used for manufacturing the semiconductor device of the first embodiment;

FIG. 3B is a cross-sectional view taken along line B-B′ shown in FIG. 3A;

FIG. 4A is a plan view illustrating a support board used for manufacturing the semiconductor device of the first embodiment;

FIG. 4B is a cross-sectional view taken along line C-C′ shown in FIG. 4A;

FIGS. 5 to 7D are cross-sectional views indicative of a process flow illustrating a method of manufacturing the semiconductor device of the first embodiment;

FIG. 8 is a plan view illustrating a semiconductor device according to a second embodiment of the present invention;

FIG. 9 is a cross-sectional view taken along line D-D′ shown in FIG. 8;

FIGS. 10A to 11D are cross-sectional views indicative of a process flow illustrating a method of manufacturing the semiconductor device of the second embodiment;

FIG. 12 is a plan view illustrating a semiconductor device according to a third embodiment of the present invention;

FIG. 13 is a cross-sectional view taken along line E-E′ shown in FIG. 12;

FIG. 14A is a plan view illustrating a wiring board used for manufacturing the semiconductor device of the third embodiment;

FIG. 14B is a cross-sectional view taken along line F-F′ shown in FIG. 14A;

FIG. 15A is a plan view illustrating a support board used for manufacturing the semiconductor device of the third embodiment;

FIG. 15B is a cross-sectional view taken along line G-G′ shown in FIG. 15A; and

FIGS. 16A to 17D are cross-sectional views indicative of a process flow illustrating a method of manufacturing the semiconductor device of the third embodiment.

### DETAILED DESCRIPTION OF THE PREFERRED EMBODIMENTS

The present invention will now be described herein with reference to illustrative embodiments. The accompanying drawings explain a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

### First Embodiment

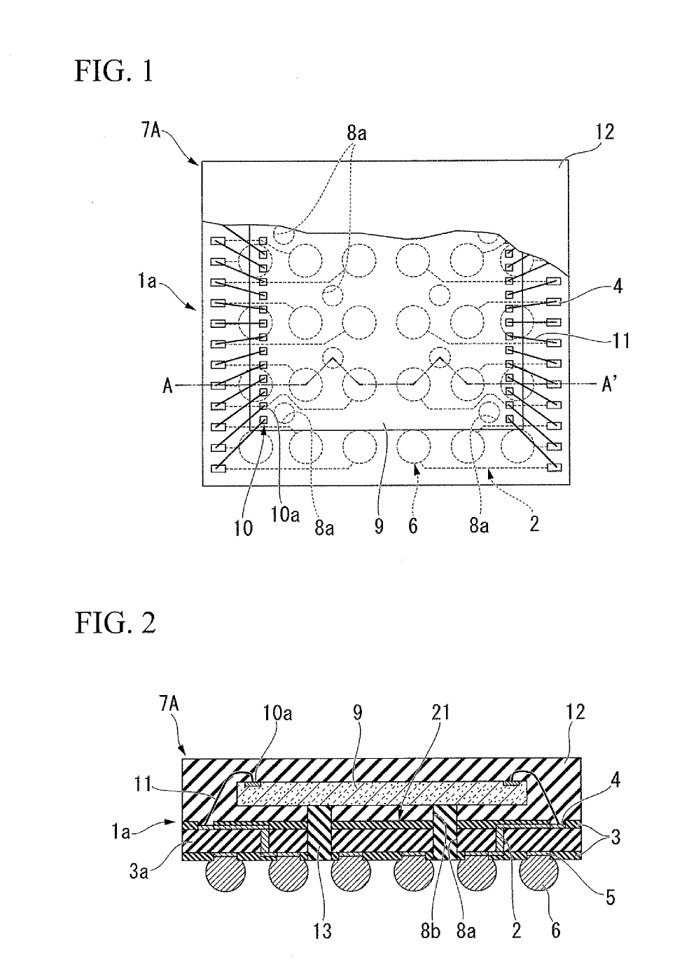

A BGA semiconductor device 7A according to a first embodiment of the present invention is explained in detail with reference to the accompanying drawings. FIG. 1 is a plan view illustrating the semiconductor device 7A of the first embodiment. FIG. 2 is a cross-sectional view taken along line A-A′ shown in FIG. 1.

The semiconductor device 7A schematically includes: a wiring board 1a having multiple through-holes 8a; a semiconductor chip 9 separated from the wiring board 1a; a first seal resin 12 covering the semiconductor chip 9 and a main surface of the wiring board 1a; and a second seal resin 13 filling the through-holes 8a, the second seal resin 13 being connected to the first seal resin 12.

A line of electrode pads 10 includes multiple electrode pads 10a aligned in one or more lines. The electrode pads 10a are connected to respective connection pads 4 on the main surface of the wiring board 1a using multiple conductive wires 11. The connection pads 4 are connected to respective lands 5 on a rear surface of the wiring board 1a through multiple wires 2 in the wiring board 1a. Solder balls 6 are provided on the respective lands 5, thus forming external terminals.

The wiring board 1a is substantially rectangular in shape, and made of a glass epoxy board having a thickness of, for example, 0.2 mm. The wires 2 are provided on both surfaces of a base board 3a of the wiring board 1a. The wiring board 1a is partially covered by an insulating film 3, such as a solder resist film. The connection pads 4 are provided on portions of the wires 2 on the main surface of the wiring board 1a, the portions of wires 2 being not covered by the insulating film 3.

The lands 5 are provided on portions of the wires 2 on the rear surface of the wiring board 1a, the portions of the wires 2 being not covered by the insulating film 3. The connection pads 4 and the respective lands 5 are electrically connected through the wires 2. The solder balls 6 are arranged in a grid at a predetermined pitch on the respective lands 5 arranged in a grid on the rear surface of the wiring board 1a. The solder balls 6 form external terminals.

The through-holes 8a are formed in a chip region 21 of the wiring board 1a. The through-holes 8a are formed in the center and four-corner regions of the chip region 21.

The semiconductor chip 9 is disposed substantially 10 μm above the chip region 21 of the wiring board 1a through the first seal region 12. Although not shown, a circuit, such as a logic circuit or a memory circuit, is formed on the main surface of the semiconductor chip 9.

The electrode pads 10a are aligned in one or more lines on a periphery of the main surface of the semiconductor chip 9. The electrode pads 10a form the line of electrode pads 10. A passivation film (not shown) is formed so as to cover an upper surface of the semiconductor chip 9 excluding portions of the electrode pads 10a, thus protecting a circuit formation surface.

The electrode pads 10a are connected, using conductive wires 11, to the respective connection pads 4 on an element formation portion 20 of the wiring board 1a. The connection pads 4 and the respective electrode pads 10a are electrically connected using the wires 11. The wires 11 are made of Au, Cu, and the like.

The first seal resin 12 is formed so as to entirely cover the semiconductor chip 9 and the wires 11. The first seal resin 12 is made of, for example, a thermosetting resin, such as an epoxy resin. The first seal resin 12 also fills a space between the wiring board 1a and the semiconductor chip 9.

The holes 8b are formed so as to penetrate the first seal resin 12 filling the space between the semiconductor chip 9 and the wiring board 1. The holes 8b connect to the through-holes 8a. Thus, the rear surface of the semiconductor chip 9 on the side of the wiring board 1a is partially exposed through the holes 8b and the through-holes 8a. The second seal resin 13 made of a thermosetting resin fills the through-holes 8a and the holes 8b, and thus connects to the first seal resin 12.

In the first embodiment, the second seal resin 13 penetrates the wiring board 1a and the first seal resin 12 so as to extend from the rear surface of the wiring board 1a to the rear surface of the semiconductor chip 9, thereby increasing the adhesion of the wiring board 1a and the first seal resin 12, and therefore enabling precise positioning of the first seal resin 12 with respect to the wiring board 1a.

The through-holes 8a are formed in the chip region 21 of the wiring board 1a and are smaller in size than the semiconductor chip 9. Thus, the semiconductor chip 9 can overlap the wiring board 1a in plan view, thereby enabling a Fan-in structure in which the solder balls 6, which form the external terminals, are provided on the rear surface of the wiring board 1a, which is opposite to the side of the semiconductor chip 9. The Fan-in structure enables miniaturization of the semiconductor device 7A.

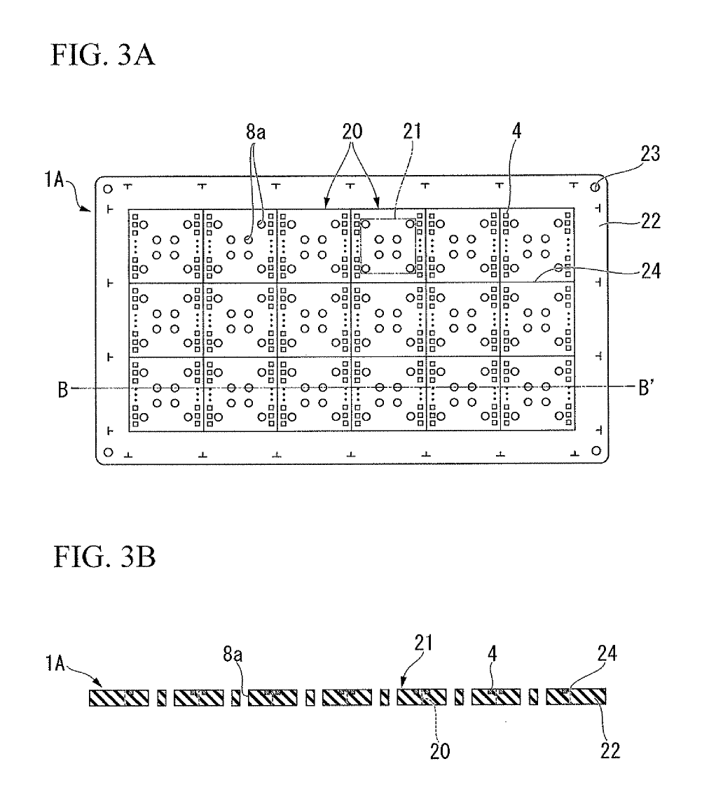

Hereinafter, a method of manufacturing the semiconductor device 7A of the first embodiment is explained with reference to FIGS. 3A to 7D. The method of the first embodiment schematically includes: a first process in which a wiring motherboard 1A and a support board 25a are prepared, and the support board 25a is attached onto the wiring motherboard 1A so that chip support portions 26a of the support board 25a protrude from the element formation portions 20; a second process in which the semiconductor chip 9 is attached onto the chip support portions 26a; a third process in which the first seal resin 12 is formed so as to cover the semiconductor chip 9; a fourth process in which the support board 25a is removed from the wiring board 1a; and a fifth process in which the second seal resin 13 is provided so as to fill the through-holes 8a in the element formation portions 20 and thus connect to the first seal resin 12. Hereinafter, each process is explained in detail.

Firstly, the wiring motherboard 1A is prepared. FIG. 3A is a plan view illustrating the wiring motherboard 1A. FIG. 3B is a cross-sectional view taken along line B-B′ shown in FIG. 3A.

The wiring motherboard 1A shown in FIG. 3A is subjected to a MAP (Mold Array Process). The wiring motherboard 1A includes multiple element formation portions 20 in a matrix. The element formation portions 20 are diced into multiple pieces, and each piece forms the wiring board 1a.

In the first embodiment, multiple through-holes 8a are formed in each chip region 21 that is the center region of each element formation portion 20. The through-holes 8a are provided for inserting thereto the chip support portions 26a. The chip support portions 26a are used for supporting the semiconductor chip 9 and upwardly extend from an upper surface of the support board 25a, as will be explained later. The shape and size of the through-holes 8a are not limited as long as the chip supporter 26a can be inserted thereto.

A frame portion 22 is provided so as to surround the element formation portions 20 arranged in a matrix on the wiring motherboard 1A. Dicing lines 24 are drawn on the boundaries among the element formation portions 20. Positioning holes 23 are provided at a predetermined pitch in the frame portion 22. The positioning holes 23 are used for transportation and positioning of the motherboard 1a.

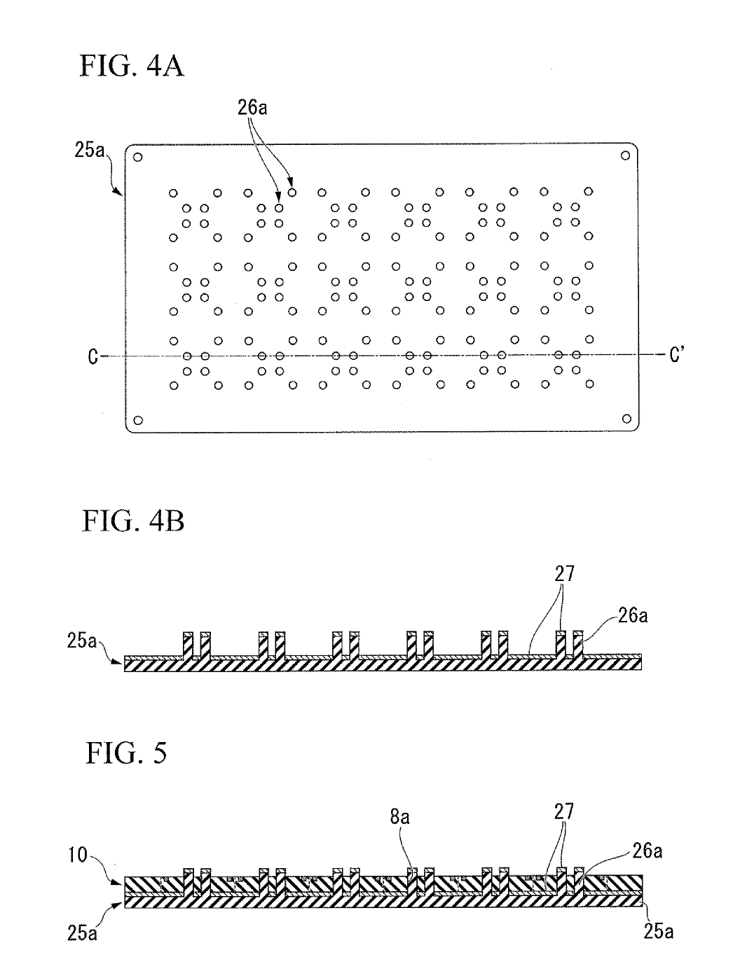

Then, the support board 25a having the chip support portions 26a is prepared as shown in FIGS. 4A and 4B. FIG. 4A is a plan view illustrating the support board 25a. FIG. 4B is a cross-sectional view taken along line C-C′ shown in FIG. 4A.

The support board 25a is substantially the same size as the wiring motherboard 1A. The positions of the chip support portions 26a of the support board 25a correspond to the positions of the through-holes 8a in the wiring motherboard 1A.

Preferably, the height of the chip support portion 26a is greater than the thickness of the wiring board 1a. The height of the chip supporter 26a is determined such that the chip support portion 26a protrudes, by approximately 10 μm, from the upper surface of the element formation portion 20 when the support board 25a is attached onto the wiring motherboard 1A, as explained later.

The chip support portion 26a extends upwardly from an upper surface of a base board of the support board 25a. The chip support portions 26a are provided in the center region and the four corners of the chip region 21 to stably support the semiconductor chip 9 in a wire-bonding process. A temporary adhesive (magic resin) layer 27 is formed so as to cover the upper surfaces of the support board 25a and the chip support portions 26a.

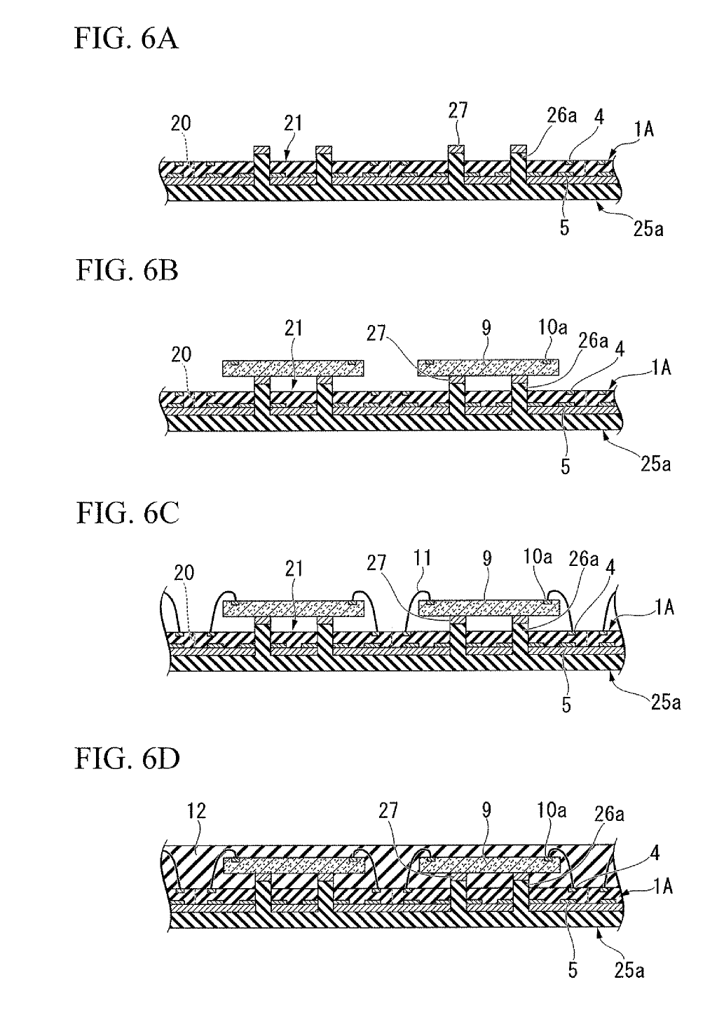

Then, the support board 25a is attached onto the wiring motherboard 1A so that the chip support portions 26a protrude from the through-holes 8a, and the wiring motherboard 1A is fixed to the support board 25a by the temporary adhesive layer 27, as shown in FIG. 5. FIG. 6A is an enlarged view of FIG. 5.

Then, the semiconductor chip 9 is attached and fixed onto top surfaces of the chip support portions 26a using the temporary adhesive layer 27, as shown in FIG. 6B. A line of electrode pads 10 is formed on the periphery of the upper surface of the semiconductor chip 9. The passivation film (not shown) is formed so as to cover the upper surface of the semiconductor chip 9 excluding the regions of the electrode pads 10a and to protect a circuit formation surface.

Then, the electrode pads 10a are electrically connected to the respective connection pads 4 by a wire-bonding apparatus (not shown) using conductive wires 11, as shown in FIG. 6C. The wires 11 are made of Au, Cu, and the like.

In the first embodiment, the through-holes 8a are formed in the center region and the four corners of the chip region 21 of each element formation portion 20, and thereby the chip support portions 26a protruding from the through-holes 8a mechanically support the semiconductor chip 9. Thus, an excellent wire-bonding process can be performed.

After all the electrode pads 10a on the semiconductor chip 9 are connected to the respective connection pads 4 on the element formation portion 20 using the wires 11, a sealing process follows in which the first seal resin 12 is formed over the element formation portion 20 so as to cover the semiconductor chip 9, as shown in FIG. 6D.

In the sealing process, the wiring motherboard 1A with the support board 25a attached thereto is set to a mold of a transfer mold apparatus (not shown). Then, the first seal resin 12, which is melted by heating, is poured into a cavity of the mold from a gate portion of the mold so that the first seal resin 12 covers the semiconductor chip 9 and the wires 11. The first seal resin 12 is made of, for example, a thermosetting resin, such as an epoxy resin. In this case, the first seal resin 12 fills the space between each element formation portion 20 and the semiconductor chip 9.

Then, the first seal resin 12 filling the cavity on the side of the wiring motherboard 1A is thermally cured at a predetermined temperature, for example, 180° C. Thus, the first seal resin 12 collectively covering the multiple element formation portions 20 of the wiring motherboard 1A is formed, as shown in FIG. 6D.

The first seal resin 12 filling the space between each element formation portion 20 and the semiconductor chip 9 is cured, and thereby the semiconductor chip 9 is disposed approximately 10 μm above the element formation portion 20.

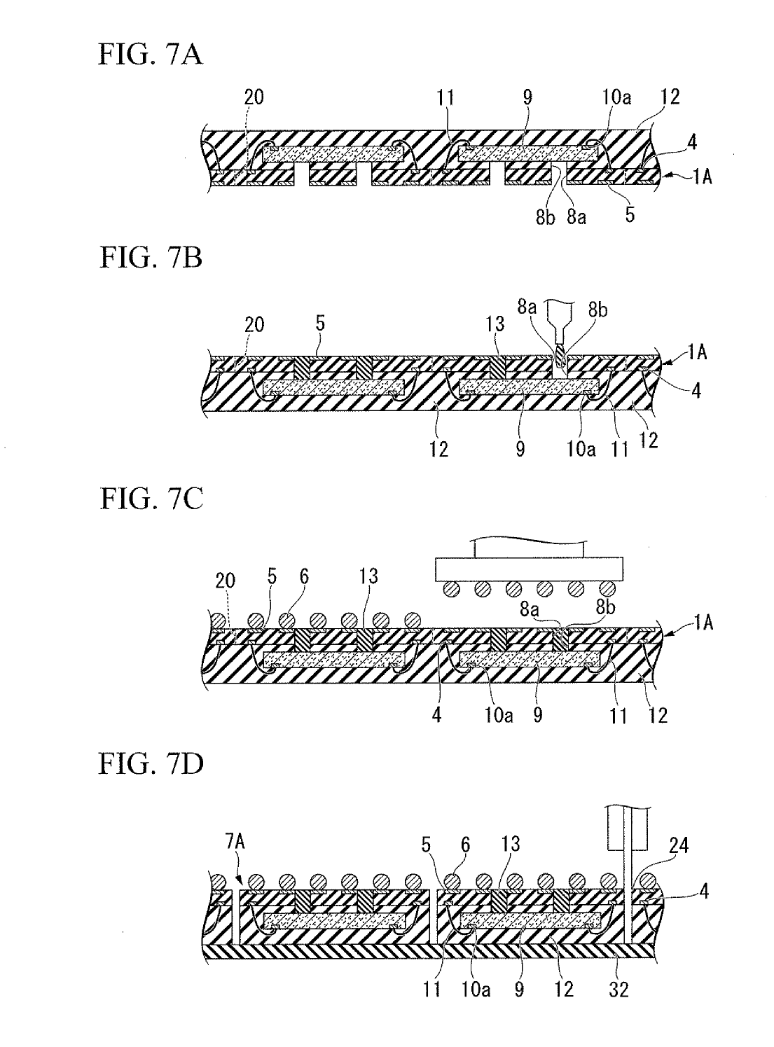

Then, the second seal resin 13 is formed as shown in FIGS. 7A and 7B. First, the support board 25a is removed from the wiring motherboard 1A so that the through-holes 8a become empty, as shown in FIG. 7A. The portions where the top portions of the chip support portions 26a have been inserted become holes 8b. The through-holes 8a connect to the respective holes 8b so that the rear surface of the semiconductor chip 9 on the side of the element formation portions 20 is partially exposed.

Then, the melted second seal resin 13 is added, by a dispenser apparatus, to the through-holes 8a and the holes 8b and thermally cured, as shown in FIG. 7B. Similar to the first seal resin 12, a thermosetting resin is used as the second seal resin 13. The second seal resin 13 is connected to the first seal resin 12.

Then, the conductive solder balls 6a are disposed on the respective lands 5 on the wiring motherboard 1A by using a ball mounting process so as to form external terminals. First, the solder balls 6 are held by a mounting tool having multiple suction holes. Then, a flux is applied onto the solder balls 6 held by the mounting tool. Then, the solder balls 6 are collectively mounted on the respective lands 5 arranged in a grid on the rear surface of the wiring motherboard 1A. After all the solder balls 6 are mounted on the wiring motherboard 1A, the wiring motherboard 1A is reflowed so that the solder balls 6 form external terminals.

After the external terminals formed by the solder balls 6 are formed, a dicing process follows as shown in FIG. 7D, and thus the semiconductor device 7A shown in FIGS. 1 and 2 is formed. First, the main surface of the wiring motherboard 1A, which is opposite to the side of the solder balls 6, is fixed onto a dicing tape 32. Then, the wiring motherboard 1A is diced by a dicing blade of a dicing apparatus (not shown) along the dicing lines 24 so as to be divided into multiple pieces of the element formation portions 20. After the dicing, the semiconductor device 7A is removed from the dicing tape 32. Thus, the semiconductor device 7A shown in FIGS. 1 and 2 is obtained.

As explained above, according to the first embodiment, the first seal resin 12 is formed so as to fill the space between the wiring board 1a and the semiconductor chip 9. Therefore, the semiconductor chip 9 is not fixed onto the wiring board 1a, thereby decreasing stress caused by the difference in thermal expansion coefficients between the semiconductor chip 9 and the wiring board 1a, and therefore enhancing the reliability of the semiconductor device 7A.

Additionally, stress applied to the solder balls 6 under the four corners of the semiconductor chip 9 decreases, thereby enhancing the reliability of the semiconductor device 7A. Further, warpage of the semiconductor device 7A, which is caused by the difference in thermal expansion coefficients between the semiconductor chip 9 and the wiring board 1a, can be reduced.

The semiconductor chip 9 is separated from the wiring board 1a, and the first and second seal resins 12 and 13 cover the entire semiconductor chip 9, thereby increasing the humidity of the semiconductor device 7A. When the semiconductor chip 9 is DRAM (Dynamic Random Access Memory), stress, which is caused by thermal expansion of the wiring substrate 1A and the first and second seal resins 11 and 12, is uniformly applied to the semiconductor chip 9, thereby reducing degradation of the refresh characteristics, and therefore increasing the refresh characteristics.

### Second Embodiment

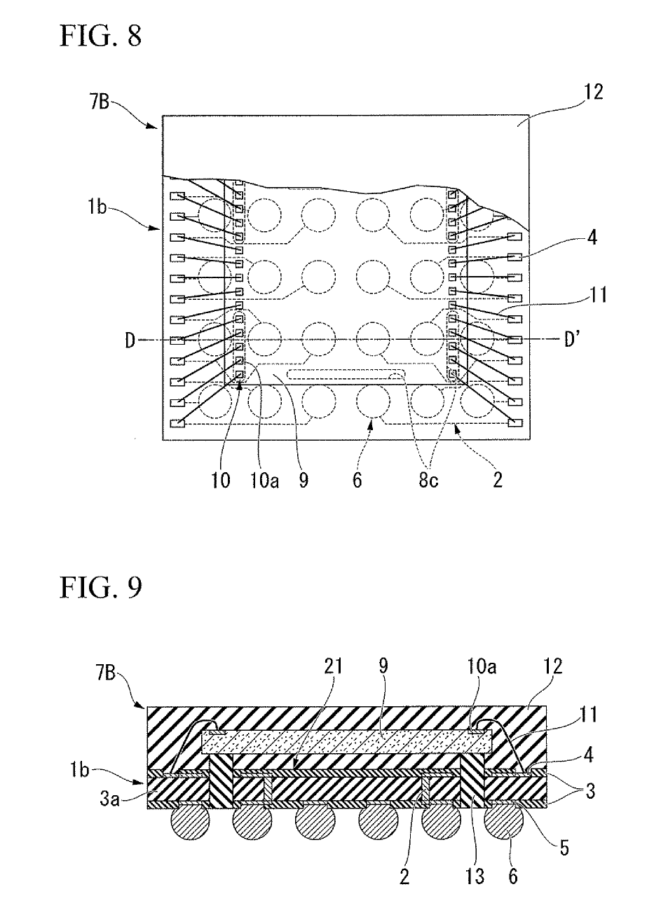

Hereinafter, a BGA semiconductor device 7B according to a second embodiment of the present invention is explained. FIG. 8 is a plan view illustrating a schematic structure of the semiconductor device 7B. FIG. 9 is a cross-sectional view taken along line D-D′ shown in FIG. 8. Like reference numerals denote like elements between the first and second embodiments.

The semiconductor device 7B includes: a wiring board 1b having slotted through-holes 8c positioned correspondingly to a line of electrode pads 10; a semiconductor chip 9 separated from the wiring board 1b; the first seal resin 12 covering the semiconductor chip 9; and the second seal resin 13 that fills the through-holes 8c, connects to the first seal resin 12, is positioned correspondingly to the line of connection pads 10, and forms a protruding portion extending along the line of electrode pads 10, the protruding portion being in a strip shape in plan view.

The electrode pads 10a on the main surface of the semiconductor chip 9 are connected to respective connection pads 4 on the main surface of the wiring board 1b using multiple wires 11. Solder balls 6 are provided on the respective lands 5 on a rear surface of the wiring board 1b, and thus form external terminals. The wiring board 1b and the semiconductor chip 9 of the second embodiment have the same structure as those of the first embodiment except for the size and position of the through-holes 8c. Therefore, explanations thereof are omitted here.

The first seal resin 12 is formed so as to entirely cover the semiconductor chip 9 and the wires 11. The first seal resin 12 is made of, for example, a thermosetting resin, such as an epoxy resin. The first seal resin 12 also fills a space between the wiring board 1b and the semiconductor chip 9.

The slotted holes 8d are formed so as to penetrate the first seal resin 12 filling the space between the semiconductor chip 9 and the wiring board 1b. The holes 8d connect to the through-holes 8c. Thus, the rear surface of the semiconductor chip 9 on the side of the wiring board 1b is partially exposed through the holes 8d and the through-holes 8c.

The second seal resin 13 made of a thermosetting resin fills the through-holes 8e and the holes 8d. Thus, the second seal resin 13, in a strip shape in plan view, forms a protruding portion extending along the line of electrode pads 10, and is positioned correspondingly to the line of electrode pads 10.

In the second embodiment, the second seal resin 13 penetrates the wiring board 1b and the first seal resin 11 so as to extend from the rear surface of the wiring board 1b to the rear surface of the semiconductor chip 9, thereby increasing the adhesion of the wiring board 1b and the first seal resin 12, and therefore enabling precise positioning of the first seal resin 12 with respect to the wiring board 1b.

The through-holes 8c are formed in the chip region 21 of the wiring board 1b and are smaller in size than the semiconductor chip 9. Thus, the semiconductor chip 9 can overlap the wiring board 1b in plan view, thereby enabling a Fan-in structure in which the solder balls 6, which will form the external terminals, are provided on the rear surface of the wiring board 1b, which is opposite to the side of the semiconductor chip 9. The Fan-in structure enables miniaturization of the semiconductor device 7B.

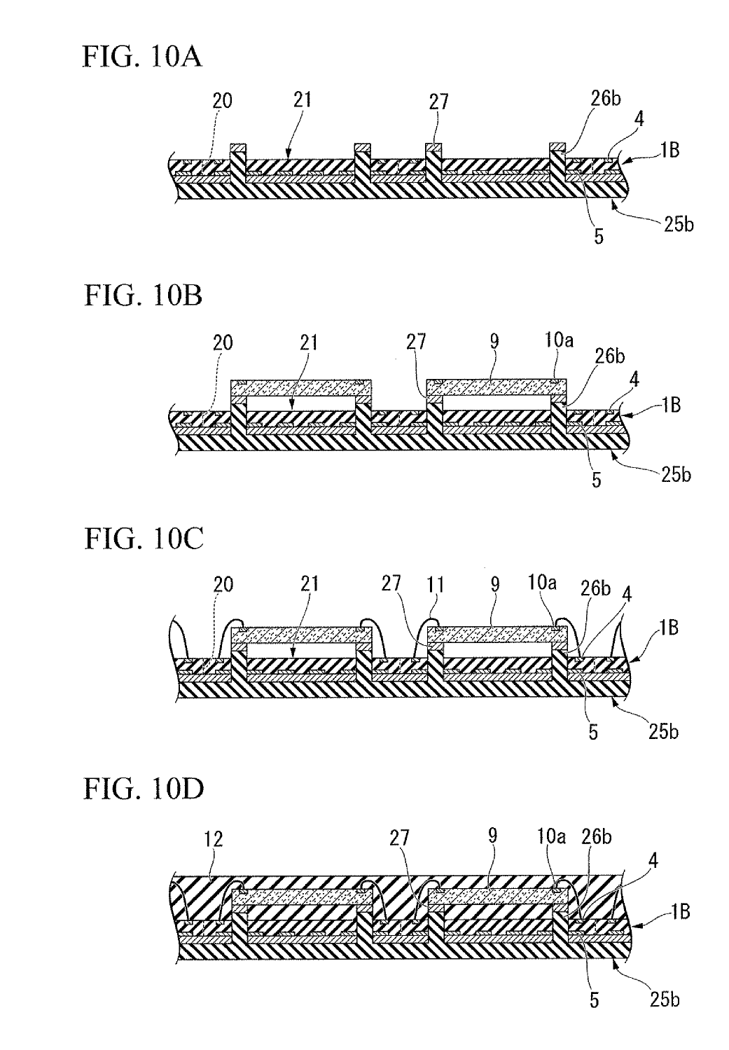

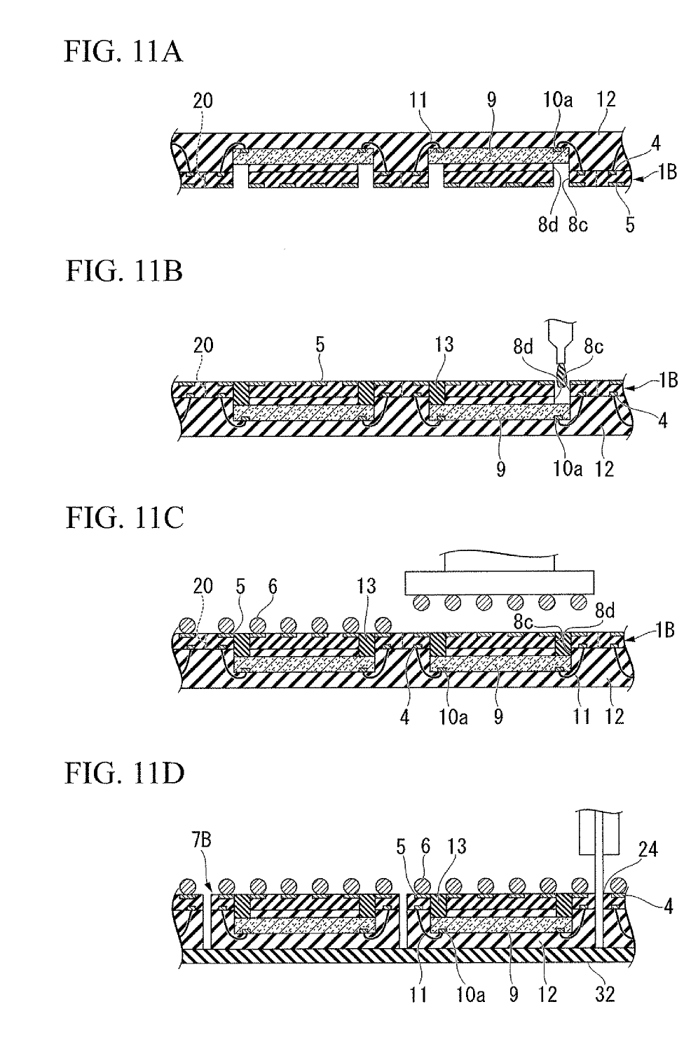

Hereinafter, a method of manufacturing the semiconductor device 7B of the second embodiment is explained with reference to FIGS. 10A to 11D. The method of the second embodiment schematically includes: a first process in which a wiring motherboard 1B and a support board 25b are prepared, the wiring motherboard 1B having the slotted through-holes 8c positioned correspondingly to the line of electrode pads 10, and the support board 25b is attached onto the wiring motherboard 1B so that chip support portions 26b of the support board 25b protrude from the element formation portions 20; a second process in which the semiconductor chip 9 is attached onto the chip support portions 26b and wire-bonding is carried out; a third process in which the first seal resin 12 is formed so as to cover the semiconductor chip 9; a fourth process in which the support board 25b is removed from the wiring board 1b; and a fifth process in which the second seal resin 13 is provided so as to fill the through-holes 8c in the element formation portions 20 and thus connect to the first seal resin 12. The difference from the first embodiment is in that the shapes and positions of the through-holes 8c and the holes 8d, and the second seal resin 13 differ from those of the first embodiment. Hereinafter, each process is explained in detail.

First, the wiring motherboard 1B and a support board 25b are prepared. The wiring motherboard 1B has slotted through-holes 8c. The support board 25b includes chip support portions 26b whose position and shape correspond to those of the through-holes 8c, which are in a strip shape in plan view, and which form protruding portions extending along the line of electrode pads 10. The slotted through-holes 8c are positioned correspondingly to the line of electrode pads 10.

The wiring motherboard 1B and the chip support portions 26b have the same structures as those of the wiring motherboard 1A and the chip support portions 26a of the first embodiment except for the positions and shapes of the through-holes 8c and the chip support portions 26b. Therefore, explanations thereof are omitted here.

Then, the support board 25b is attached onto the wiring motherboard 1B so that the chip support portions 26b protrude from the through-holes 8a, and the wiring motherboard 113 is fixed to the support board 25b by the temporary adhesive layer 27.

Then, the semiconductor chip 9 is attached and fixed onto top surfaces of the chip support portions 26b using the temporary adhesive layer 27, as shown in FIGS. 10A and 1013. FIG. 10A illustrates a state where the wiring motherboard 1B is fixed onto the support board 25h.

A line of electrode pads 10 is formed on the periphery of the upper surface of the semiconductor chip 9. The chip support portions 26b mechanically support the semiconductor chip 9 from the rear surface thereof on the side of the element formation portions 20 at the positions corresponding to the line of electrode pads 10. The structure of the semiconductor chip 9 is the same as that of the first embodiment, and therefore explanations thereof are omitted here.

Then, the electrode pads 10a are electrically connected to the respective connection pads 4 by a wire-bonding apparatus (not shown) using conductive wires 11, as shown in FIG. 10C. The wires 11 are made of Au, Cu, and the like. In the second embodiment, the chip support portions 26b mechanically support, during the wire-bonding process, the semiconductor chip 9 from the rear surface thereof on the side of the element formation portions 20 at the positions corresponding to the line of electrode pads 10. Thus, an excellent wire-bonding process can be carried out.

After all the electrode pads 10a on the semiconductor chip 9 are connected to the respective connection pads 4 on the element formation portion 20 using the wires 11, a sealing process follows in which the first seal resin 12 is formed over the element formation portion 20 so as to cover the semiconductor chip 9, as shown in FIG. 10D. The sealing process is the same as that of the first embodiment, and therefore explanation thereof is omitted here.

Then, the second seal resin 13 is formed as shown in FIGS. 11A and 1113. First, the support board 25b is removed from the wiring motherboard 1B so that the through-holes 8c become empty, as shown in FIG. 11A. The portions where the top portions of the chip support portions 26b have been inserted become holes 8d. The through-holes 8c connect to the respective holes 8d so that the rear surface of the semiconductor chip 9 on the side of the element formation portions 20 is partially exposed.

Then, the melted second seal resin 13 is added, by a dispenser apparatus, to the through-holes 8c and the holes 8d and thermally cured, as shown in FIG. 11B. The second seal resin 13 is connected to the first seal resin 12.

Then, a ball mounting process shown in FIG. 11C and a dicing process shown in FIG. 11D are sequentially carried out, and thus the semiconductor device 7B shown in FIGS. 8 and 9 is obtained. The ball mounting process and the dicing process are the same as those of the first embodiment, and therefore explanations thereof are omitted here.

As explained above, according to the second embodiment, the chip support portions 26b are positioned correspondingly to the line of electrode pads 10 on the semiconductor chip 9. The chip support portions 26b and the support board 25b mechanically support the semiconductor chip 9 from the rear surface thereof on the side of the element formation portions 20, thereby preventing chip cracking and enabling an excellent wire-bonding process.

### Third Embodiment

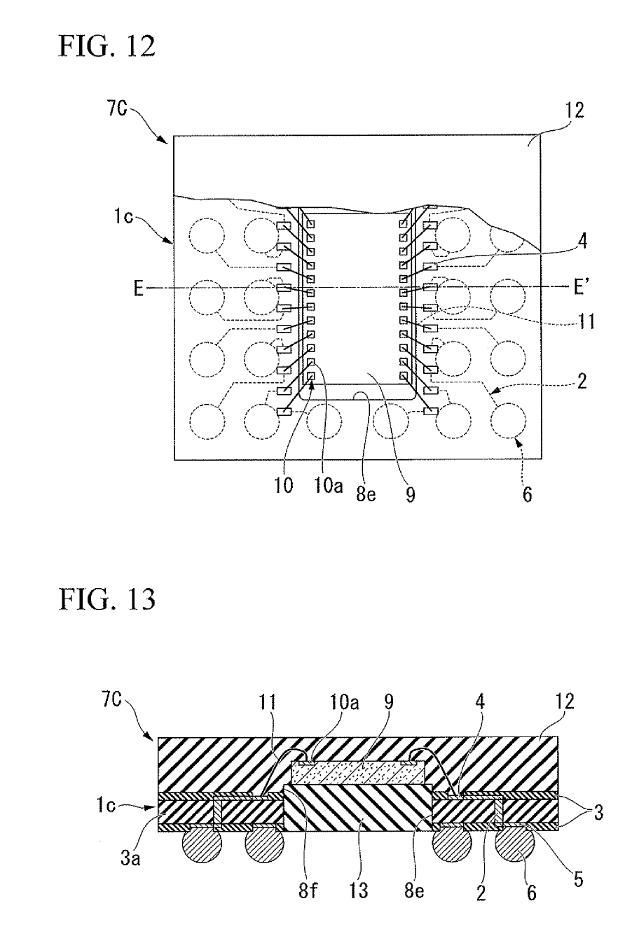

Hereinafter, a BGA semiconductor device 7C according to a third embodiment of the present invention is explained. FIG. 12 is a plan view illustrating a schematic structure of the semiconductor device 7C. FIG. 13 is a cross-sectional view taken along line E-E′ shown in FIG. 12. Like reference numerals denote like elements among the first to third embodiments.

The semiconductor device 7C includes: a wiring board 1c having only one through-hole 8e that is larger in size than the semiconductor chip 9 in plan view; a semiconductor chip 9 separated from the wiring board 1c; the first seal resin 12 covering the semiconductor chip 9; and the second seal resin 13 that fills the through-hole 8e, covers the entire rear surface of the semiconductor chip 9, and connects to the first seal resin 12.

The electrode pads 10a on the main surface of the semiconductor chip 9 are connected to respective connection pads 4 on the main surface of the wiring board 1c using multiple wires 11. Solder balls 6 are provided on the respective lands 5 on a rear surface of the wiring board 1c, and thus form external terminals. The wiring board 1c and the semiconductor chip 9 of the second embodiment have the same structure as those of the first embodiment except for the size and position of the through-hole 8e. Therefore, explanations thereof are omitted here.

The first seal resin 12 is formed so as to entirely cover an upper surface of the semiconductor chip 9 and the wires 11. The difference from the first and second embodiments is in that the first seal resin 12 is not present in the space between the wiring board 1c and the semiconductor chip 9. The semiconductor chip 9 is disposed substantially 10 μm above the chip region 21 of the wiring board 1c through the first seal region 12.

The hole 8f, which is larger in size than the chip region 21, is formed between the semiconductor chip 9 and the wiring board 1c so that the entire rear surface of the semiconductor chip 9 is exposed. The hole 8f connects to the through-hole 8e. The second seal resin 13 made of a thermosetting resin fills the through-hole 8e and the hole 8f, and thus connects to the first seal resin 12.

In the second embodiment, the second seal resin 13 penetrates the wiring board 1c and the first seal resin 11 so as to extend from the rear surface of the wiring board 1c to the rear surface of the semiconductor chip 9, thereby increasing the adhesion of the wiring board 1c and the first seal resin 12, and therefore enabling precise positioning of the first seal resin 12 with respect to the wiring board 1c.

Hereinafter, a method of manufacturing the semiconductor device 7C of the third embodiment is explained with reference to FIGS. 12 to 17D. The method of the third embodiment schematically includes: a first process in which a wiring motherboard 1C and a support board 25c are prepared, the wiring motherboard 1C having a through-hole 8e that is larger in size than the chip region 21, i.e., the semiconductor chip 9 in plan view, and the support board 25c is attached onto the wiring motherboard 1C so that chip support portions 26c of the support board 25c protrude from the element formation portions 20; a second process in which the semiconductor chip 9 is attached by vacuum suction onto the chip support portions 26c, and then wire-bonding is carried out on the electrode pads 10a; a third process in which the first seal resin 12 is formed so as to cover the semiconductor chip 9; a fourth process in which the support board 25c is removed from the wiring board 1c; and a fifth process in which the second seal resin 13 is formed so as to fill the through-hole 8e in the element formation portion 20 and thus connect to the first seal resin 12. Hereinafter, each process is explained in detail.

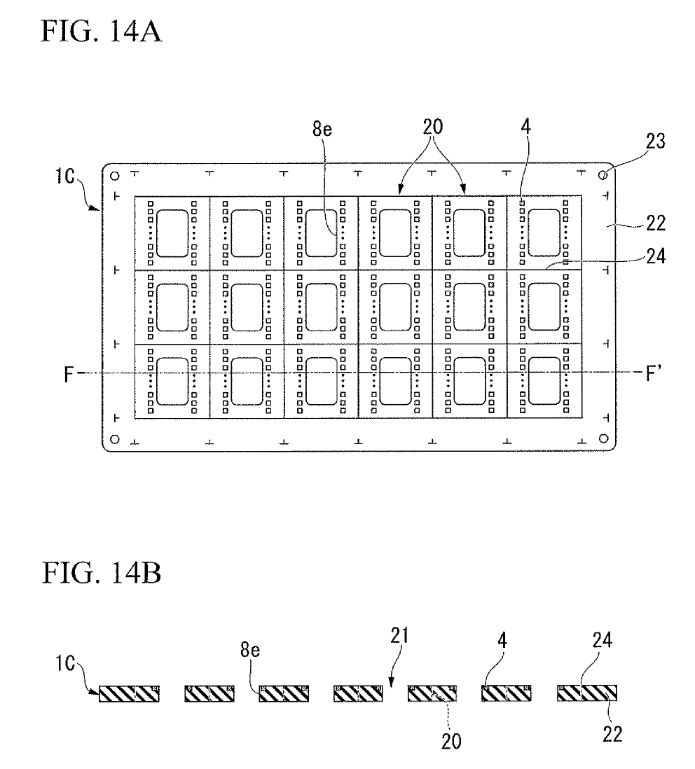

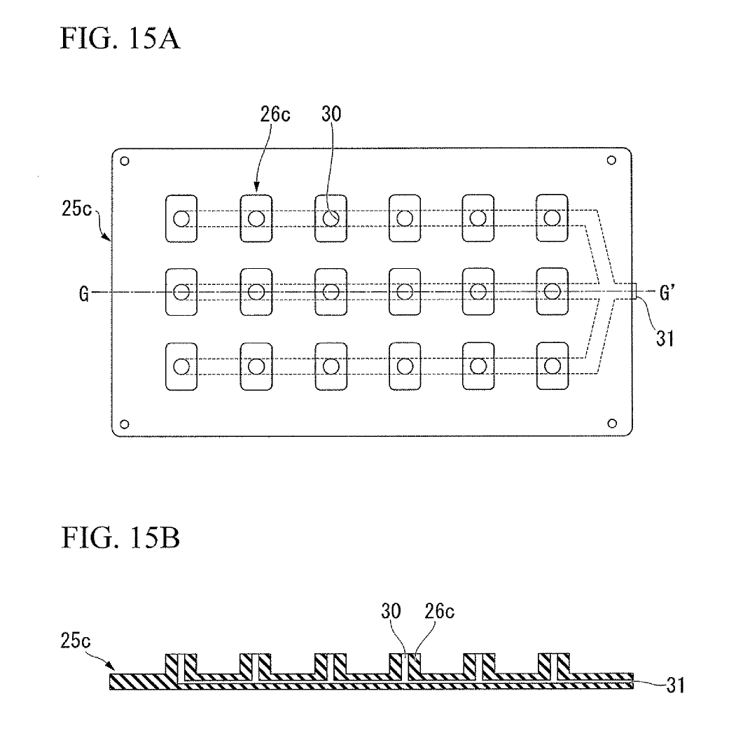

First, the wiring motherboard 1C shown in FIGS. 14A and 14B, and the support board 25c shown in FIGS. 15A and 15B are prepared. FIG. 14A is a plan view illustrating the wiring motherboard 1C. FIG. 15B is a cross-sectional view taken along line F-F′ shown in FIG. 14A.

The wiring motherboard 1C includes multiple element formation portions 20 in a matrix. The element formation portions 20 are diced into multiple pieces, and each piece becomes the wiring board 1c. Each element formation portion 20 has the through-hole 8e that is larger in size than the chip region 21, i.e., the semiconductor chip 9 in plan view. The structure of the wiring motherboard 1C is the same as that of the wiring motherboard 1A of the first embodiment except for the position and shape of the through-hole 8e. Therefore, explanations of elements other than the through-hole 8e are omitted here.

FIG. 15A is a plan view illustrating the support board 25c. FIG. 15B is a cross-sectional view taken along line G-G′ shown in FIG. 15A. The support board 25c is substantially the same size as the wiring motherboard 1C. The chip support portions 26c, each of which is the same size as the through-hole 8e, are formed at the positions corresponding to the through-holes 8e.

The chip support portions 26c are arranged to stably support the entire rear surface of the semiconductor chip 9 in the wire-bonding process. Each chip support portion 26c has a suction hole 30. Each suction hole 30 connects to an exhaust hole 31 provided at the edge of the support board 25c. Vacuum suction is carried out from the exhaust hole 31 so that the semiconductor chip 9 is attached by vacuum suction onto the chip support portions 26c.

Preferably, the height of the chip support portion 26c is greater than the thickness of the wiring board 1c. The height of the chip support portion 26c is determined such that the chip support portion 26c protrudes, by approximately 10 μm, from the upper surface of the element formation portion 20 when the support board 25c is attached onto the wiring motherboard 1C, as explained later. Different from the first and second embodiments, the temporary adhesive layer 27 is not provided on the upper surfaces of the support board 25c and the chip support portions 26c.

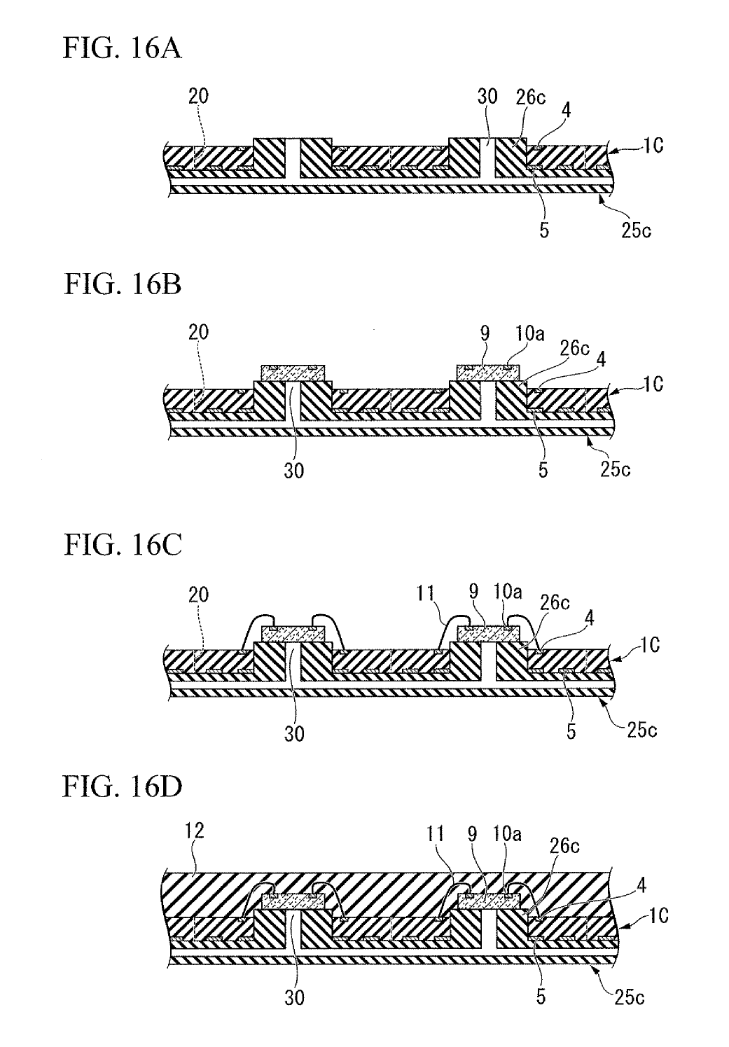

Then, the support board 25c is attached onto the wiring motherboard 1C so that the chip support portions 26c protrude from the through-holes 8e, as shown in FIG. 16A. Then, the semiconductor chip 9 is attached and fixed, by vacuum suction, onto top surfaces of the chip support portions 26c, as shown in FIG. 16B. The structure of the semiconductor chip 9 is the same as that of the first embodiment, and therefore explanation thereof is omitted here.

Then, the electrode pads 10a are electrically connected to the respective connection pads 4 by a wire-bonding apparatus (not shown) using conductive wires 11 while the semiconductor chip 9 is fixed by vacuum suction onto the top surface of the chip support portion 26c, as shown in FIG. 16C. The wires 11 are made of Au, Cu, and the like. In the third embodiment, the chip support portion 26c protruding from the through-hole 8c mechanically supports the entire semiconductor chip 9 from the rear surface thereof on the side of the element formation portions 20. Thus, an excellent wire-bonding process can be performed.

After all the electrode pads 10a on the semiconductor chip 9 are connected to the respective connection pads 4 on the element formation portion 20 using the wires 11, a sealing process follows. In the sealing process, the first seal resin 12 is formed over the element formation portion 20 so as to cover the semiconductor chip 9 while the semiconductor chip 9 is fixed by vacuum suction onto the chip support portion 26c, as shown in FIG. 16D.

First, the wiring motherboard 1C with the support board 25c attached thereto is set to a mold of a transfer mold apparatus (not shown) while the semiconductor chip 9 is held by vacuum suction onto the top surface of the chip support portion 26c. Then, the first seal resin 12, which is melted by heating, is poured into a cavity from a gate portion of the mold so that the first seal resin 12 covers the semiconductor chip 9 and the wires 11.

Then, the first resin seal 12 is thermally cured. Since the melted first seal resin 12 is poured and thermally cured while the semiconductor chip 9 is held by vacuum suction onto the top surface of the chip support portion 26c, the first seal resin 12 does not cover the rear surface of the semiconductor chip 9 on the side of the element formation portion 20. The chip support portion 26c protrudes from the element formation portion 20, and therefore the semiconductor chip 9 is positioned approximately 10 μm above the element formation portion 20.

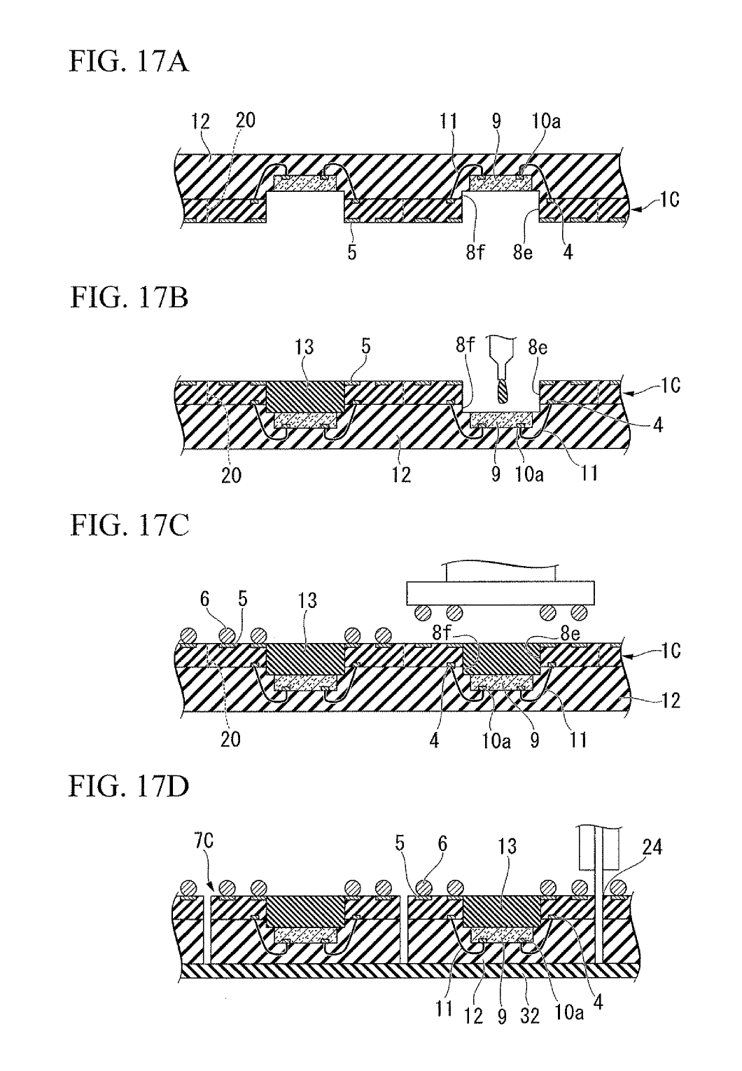

Then, the second seal resin 13 is formed as shown in FIGS. 17A and 17B. First, the support board 25c is removed from the wiring motherboard 1C so that the through-hole 8e becomes empty and the entire rear surface of the semiconductor chip 9 on the side of the element formation portion 20 is exposed, as shown in FIG. 17A. The portion where the top portion of the chip support portion 26c has been inserted becomes a hole 8f. The through-hole 8e connects to the hole 8f so that the entire rear surface of the semiconductor chip 9 on the side of the element formation portions 20 is exposed.

Then, the melted second seal resin 13 is added, by a dispenser apparatus, to the through-hole 8e and the hole 8f and thermally cured, as shown in FIG. 17B. Thus, the second seal resin 13, which covers the entire rear surface of the semiconductor chip 9 on the side of the element formation portion 20, is formed. Similar to the first seal resin 12, a thermosetting resin is used as the second seal resin 13. The second seal resin 13 is connected to the first seal resin 12.

Then, a ball mounting process shown in FIG. 17C and a dicing process shown in FIG. 17D are sequentially carried out. Thus, the semiconductor device 7C shown in FIGS. 12 and 13 is obtained. The ball mounting process and the dicing process are the same as those of the first embodiment, and therefore explanations thereof are omitted here.

As explained above, according to the third embodiment, the through-hole 8e and the chip support portion 26c are larger in size than the chip region 21 in plan view. Therefore, the chip support portion 26c stably and mechanically supports the entire rear surface of the semiconductor chip 9, thereby enabling an excellent wire-bonding process.

It is apparent that the present invention is not limited to the above embodiments, but may be modified and changed without departing from the scope and spirit of the invention.

For example, although it has been explained in the first to third embodiments that one semiconductor chip 9 is provided for each of the wiring board 1a to 1c, multiple semiconductor chips 9 may be provided in parallel or stacked for each of the wiring boards 1a to 1c.

Although it has been explained in the first to third embodiments that each of the wiring boards 1a to 1c is made of a glass epoxy material, each of the wiring boards 1a to 1c may be a flexible wiring board made of a polyimide material. Although it has been explained in the above embodiments that a line of electrode pads 10 including multiple electrode pads 10a is provided on the periphery of the semiconductor chip 9, the line of electrode pads 10 may be provided in the center region of the semiconductor chip 9.

As used herein, the following directional terms “forward,” “rearward,” “above,” “downward,” “vertical,” “horizontal,” “below,” and “transverse,” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percent of the modified term if this deviation would not negate the meaning of the word it modifies.

What is claimed is:

1. A semiconductor device comprising:
a wiring board;
a first insulator penetrating the wiring board, a top end of the first insulator being higher in level than an upper surface of the wiring board;
a semiconductor chip on the top end of the first insulator, the semiconductor chip being separated from the upper surface of the wiring board; and
a second insulator covering the semiconductor chip and the upper surface of the wiring board.

2. The semiconductor device according to claim 1, wherein the second insulator is connected to the first insulator.

3. The semiconductor device according to claim 1, wherein the first and second insulators are made of thermosetting resin.

4. The semiconductor device according to claim 1, wherein the first insulator is positioned inside the semiconductor chip in plan view.

5. The semiconductor device according to claim 4, wherein the first insulator is positioned on a periphery of the semiconductor chip in plan view.

6. The semiconductor device according to claim 4, wherein the first insulator is positioned in the center region of the semiconductor chip in plan view.

7. The semiconductor device according to claim 4, wherein the first insulator is positioned under each corner of the semiconductor chip.

8. The semiconductor device according to claim 5, wherein the first insulator has a strip shape in plan view.

9. The semiconductor device according to claim 4, wherein the second insulator fills a space between the semiconductor chip and the wiring board.

10. The semiconductor device according to claim 5, wherein the first insulator is positioned under a plurality of electrode pads provided on an upper surface of the semiconductor chip.

11. The semiconductor device according to claim 1, wherein the semiconductor chip is positioned inside the first insulator in plan view.

12. The semiconductor device according to claim 11, wherein
the first insulator entirely covers a rear surface of the semiconductor chip,
the first insulator is fixed on the rear surface of the semiconductor chip, and
the second insulator covers upper and side surfaces of the semiconductor chip.

13. The semiconductor device according to claim 11, wherein the first insulator has a rectangular shape in plan view.

14. A method of manufacturing a semiconductor device, comprising:
preparing a motherboard having a plurality of through-holes;
attaching a support board onto the motherboard, the support board having a plurality of protruding portions, the plurality of protruding portions being inserted into the plurality of through-holes, so that top ends of the plurality of protruding portions are higher in level than an upper surface of the motherboard;
fixing a plurality of semiconductor chips to the top ends of the plurality of protruding portions so that the plurality of semiconductor chips are separated from the upper surface of the motherboard;
forming a first insulator covering the plurality of semiconductor chips;
removing the support board; and
forming a second insulator so as to fill a plurality of spaces into which the plurality of protruding portions have been inserted, the second insulator being connected to the first insulator.

15. The method according to claim 14, wherein
the motherboard comprises a plurality of element formation portions, and
each of the plurality of element formation portions comprises a chip region for positioning one of the plurality of semiconductor chips.

16. The method according to claim 15, wherein preparing the motherboard comprises forming at least two of the plurality of through-holes in a center region of the chip region.

17. The method according to claim 15, wherein preparing the motherboard comprises forming at least two of the plurality of through-holes on respective corners of the chip region.

18. The method according to claim 15, wherein preparing the motherboard comprises forming at least two of the plurality of through-holes on a periphery of the chip region, each of the plurality of through-holes having a slotted shape in plan view.

19. The method according to claim 14, wherein
the motherboard comprises a plurality of element formation portions, and
preparing the motherboard comprises forming each of the plurality of through-holes in a center region of each of the plurality of element formation portions, each of the plurality of through-holes being larger in size than each of the plurality of semiconductor chips in plan view.

20. The method according to claim 14, wherein
the support board has a plurality of suction holes extending along the plurality of protruding portions, and
the plurality of semiconductor chips are fixed, by vacuum suction, to the top ends of the plurality of protruding portions.
